(19) United States
(12) Patent Application Publication
(10) Pub. No.: US 2025/0331586 A1
(43) Pub. Date: Oct. 30, 2025

(54) TEMPERATURE SENSOR FOR WEARABLE DEVICES

(71) Applicant: FIBRA INC., Vaughan (CA)

(72) Inventors: Parnian MAJD, Vaughan (CA); Milad GHALAMBORAN, Aurora (CA)

(21) Appl. No.: 19/191,770

(22) Filed: Apr. 28, 2025

Related U.S. Application Data
(60) Provisional application No. 63/639,266, filed on Apr. 26, 2024.

(51) Int. Cl. A41D 31/04; G01K 7/16; G01K 13/20; H05K 1/03; H05K 1/09; H05K 1/16

(52) U.S. Cl. CPC A41D 31/04; G01K 7/16; H05K 1/038; H05K 1/092; H05K 1/16; G01K 13/20; H05K 2201/10151

(57) ABSTRACT

The specification provides a temperature sensor integrated into textiles, and manufacturing methods thereof. The temperature sensor comprises a sensing layer made from a mixture of poly(3,4-ethylenedioxythiophene):poly(styrenesulfonate) (PEDOT:PSS) and reduced graphene oxide, applied to textile surfaces. This layer is connected to two silver electrodes, facilitating temperature detection via signal processing executed by a microcontroller. The microcontroller applies a input signal through one electrode and captures the feedback signal from the other to accurately compute the temperature. The manufacturing process of this sensor includes inkjet-printing the sensing layer onto the textile and applying silver electrodes using either drop-casting or extrusion-printing methods. These production techniques ensure precise electrode placement and scalable manufacturing, making the sensor ideal for wearable technology, where flexibility and durability are valuable.

This application claims priority to U.S. Provisional Patent Application No. 63/639,266, titled “TEMPERATURE SENSOR FOR WEARABLE DEVICES” filed on Apr. 26, 2024, the contents of which are incorporated herein by reference.

### FIELD

The present application relates generally to wearable devices, and specifically to a temperature sensor for wearable devices.

### BACKGROUND

Wearable devices, known as “smart textiles”, integrate sensors and fabrics for real-time monitoring of physiological parameters like heart rate and body temperature while maintaining garment comfort. Smart textiles are becoming increasingly prevalent in healthcare, fitness, and consumer electronics applications, as skin temperature can offer valuable insights into user health and environmental interactions. However, designing a sensor that is both accurate and seamlessly integrated into the textile remains a challenge.

Conventional flexible temperature sensors often rely on conductive materials such as carbon nanotubes or metallic fillers deposited on fiber substrates. For example, Chinese Patent Application Publication No. 114235212 (“the 212 application”) describes three-dimensional fiber matrices coated with conductive nanomaterials. The application discloses measuring resistance changes due to thermal expansion and contraction of the fiber matrices, which modifies conductive pathways. While such systems offer flexibility and environmental durability, they may suffer from indirect sensing, lower resolution, and variability due to mechanical deformation and sweat interference.

Moreover, the 212 application discloses soaking and drying techniques to apply conductive or hydrophobic coatings to substrates. This process limits the precision and reproducibility of sensor manufacturing.

Accordingly, wearable devices still face challenges providing sensors that are flexible for comfort and movement, durable for daily wear, and quick to produce for scalability and cost-efficiency. High reproducibility across batches is also desirable for maintaining quality standards and user satisfaction.

### SUMMARY

According to one aspect, the specification provides a temperature sensor for a wearable device. The temperature sensor includes a sensing layer, two spaced-apart silver electrodes, and a microcontroller. The sensing layer includes a textile and a temperature-sensitive compound applied to a surface of the textile. The temperature-sensitive compound includes poly(3,4-ethylenedioxythiophene):poly(styrenesulfonate) (PEDOT:PSS) and reduced graphene oxide (rGO) dispersed within the temperature-sensitive compound. The two spaced-apart silver electrodes are electrically coupled to the sensing layer and include a first electrode and a second electrode. The microcontroller is configured to apply an input signal to the sensing layer via the first electrode; receive a feedback signal via the second electrode; and compute a temperature based on the feedback signal.

The textile may be part of a wearable article. The temperature sensor may be positioned on the wearable article to contact the skin of a user when the wearable article is worn.

The sensing layer may be applied directly to the textile via inkjet-printing. The electrodes may comprise a silver conductive paste applied to the textile via drop-casting or extrusion-printing.

The microcontroller may comprise a wireless transceiver configured to transmit the computed temperature to an external computing device.

The temperature-sensitive compound may include about: 80-90 wt % of an aqueous dispersion of PEDOTPSS, wherein the PEDOT:PSS solid content is approximately 1.3 wt %; 0.5-2 wt % rGO, provided as a dispersion of 1 wt % rGO in water or dimethyl sulfoxide (DMSO); 1-3 wt % 4-dodecylbenzenesulfonic acid (DBSA), relative to the solid content of PEDOT:PSS; 0.1-0.5 wt % (3-glycidyloxypropyl)trimethoxysilane (GOPS); 5-10 wt % ethylene glycol; 3-7 wt % dimethyl sulfoxide (DMSO); and deionized water comprising the balance to 100 wt %.

According to another aspect, the specification provides a method of manufacturing the temperature sensor. A sensing layer is inkjet-printed onto a textile. The sensing layer includes a temperature-sensitive compound having a mixture of poly(3,4-ethylenedioxythiophene):poly(styrenesulfonate) and reduced graphene oxide dispersed within the temperature-sensitive compound. Two spaced-apart silver electrodes are applied to the textile, such that the two electrodes are electrically coupled to the sensing layer.

The textile may be part of a wearable article. The temperature sensor may be inkjet-printed on the wearable article at a position to contact the skin of a user when the wearable article is worn.

Applying the two spaced-apart silver electrodes may include drop-casting a silver conductive paste onto the textile. Applying the two spaced-apart silver electrodes may include extrusion-printing a silver conductive paste onto the textile.

The temperature-sensitive compound may include about: 80-90 wt % of an aqueous dispersion of PEDOTPSS, wherein the PEDOT:PSS solid content is approximately 1.3 wt %; 0.5-2 wt % rGO, provided as a dispersion of 1 wt % rGO in water or dimethyl sulfoxide (DMSO); 1-3 wt % 4-dodecylbenzenesulfonic acid (DBSA), relative to the solid content of PEDOT:PSS; 0.1-0.5 wt % (3-glycidyloxypropyl)trimethoxysilane (GOPS); 5-10 wt % ethylene glycol; 3-7 wt % dimethyl sulfoxide (DMSO); and deionized water comprising the balance to 100 wt %.

Preparing the temperature-sensitive compound may include: combining the PEDOT:PSS aqueous dispersion with the rGO dispersion under continuous stirring; adding the DBSA gradually to ensure uniform doping of the PEDOT:PSS; introducing the GOPS; adding the ethylene glycol and DMSO sequentially; stirring the mixture at room temperature; and filtering the stirred mixture through a filter.

The temperature sensor features a sensing layer made from a temperature-sensitive compound that includes poly(3,4-ethylenedioxythiophene):poly(styrenesulfonate) (PEDOT:PSS) and reduced graphene oxide, applied to the surface of a textile. This sensor is equipped with two spaced-apart silver electrodes, labeled as the first and second electrodes. These electrodes are connected to the sensing layer and are configured to measure the resistance across the sensing layer. A microcontroller is configured to apply a test signal to the sensing layer via the first electrode, receive a feedback signal at the second electrode, and compute the temperature from this feedback signal.

According to a further aspect, the specification provides a method of manufacturing a temperature sensor. The method involves inkjet-printing a sensing layer directly onto a textile. This sensing layer includes a mixture of PEDOTPSS and reduced graphene oxide to create a temperature-sensitive compound. Two silver electrodes are applied to the textile such that the electrodes connect with the sensing layer.

In some examples, the silver electrodes are applied with drop-casting. In this technique, a silver conductive paste is drop-cast onto the textile to form the electrodes.

In other examples, the silver electrodes are applied using extrusion-printing. This method involves extruding a silver conductive paste onto the textile, allowing for precise control over the electrode shapes and positions.

These together with other aspects and advantages which will be subsequently apparent, reside in the details of construction and operation as more fully hereinafter described and claimed, reference being had to the accompanying drawings forming a part hereof, wherein like numerals refer to like parts throughout.

### BRIEF DESCRIPTION OF THE DRAWINGS

Embodiments are described with reference to the following figures.

FIG. 1 is a front elevation view of a wearable device.

FIG. 2 is a block diagram of a microcontroller.

FIG. 3 is a top elevation view of a temperature sensor.

FIG. 4 is a flow chart of a method for detecting temperature.

FIG. 5 is a flow chart of a method for preparing a temperature-sensitive compound.

### DETAILED DESCRIPTION

The present specification describes a temperature sensor. In some embodiments, the temperature sensor is adapted for use in a wearable device. However, the temperature sensor is not particularly limited and may be applied to other suitable textiles.

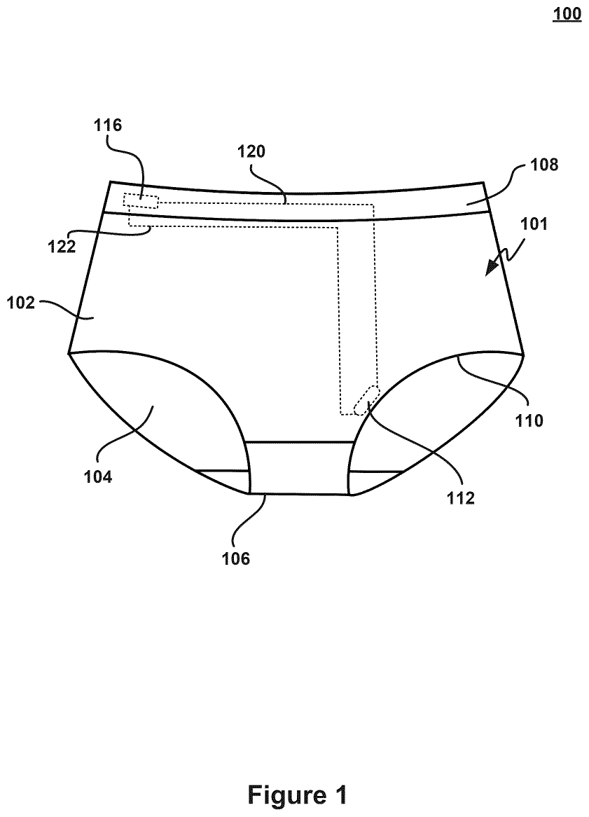

For convenience, like numerals in the description refer to like structures in the drawings. Referring to FIG. 1, a front elevation view of a wearable device is illustrated generally by numeral 100. The wearable device 100 comprises a wearable article 101 to be worn by a user, a temperature sensor 112, a microcontroller 116, a first connector 120, and a second connector 122.

In the example shown in FIG. 1, the wearable article 101 is underwear. The wearable article 101 generally comprises one or more textile portions to be worn on the user's body. In this example, the textile portions comprise a front portion 102, a rear portion 104, a gusset 106 and a waistband 108, however other configurations are contemplated. One or more of the textile portions may comprise a plurality of textile layers.

The textile portions may comprise any suitable woven or non-woven fabric. In examples where the textile portions comprise a woven fabric, the textile may include but is not limited to cotton, silk, linen, wool, polyester, nylon, rayon, modal, and a combination thereof. In specific non-limiting examples, the textile comprises a fabric blend of cotton and polyester, and in particular examples about 10% polyester and about 90% cotton. In some examples, the textile comprises about 100% cotton.

Although both polyester and cotton are electrically insulating materials, their differing thermal conductivities influence temperature sensing performance. For example, polyester has a higher thermal conductivity than cotton, which allows greater heat transfer from the environment. Such transfer can lead to interference and reduce the sensitivity of temperature measurements. In contrast, cotton's lower thermal conductivity provides better thermal isolation, minimizing external thermal effects and improving measurement accuracy. Accordingly, in some embodiments it is preferable to use cotton rather than polyester.

Although the wearable article 101 is illustrated as underwear, it is not so limited. In other embodiments, the wearable article 101 can be an undershirt, bra, headpiece, leggings, swimwear, shapewear, shirt, sock, wristband, or any suitable garment.

The temperature sensor 112 is applied to the wearable article 101. In some embodiments, the temperature sensor 112 is positioned on the wearable article 101 to contact, or be proximal to, the skin of the user when the wearable device 100 is worn. Thus, the temperature measured by the temperature sensor 112 will substantially correspond to the user's skin temperature. In the example shown in FIG. 1, the temperature sensor 112 is disposed on the front portion 102 along a leg opening 110. In this arrangement, the temperature sensor 112 is positioned proximal to the femoral artery. The skin temperature proximal to the femoral artery approximates the internal body temperature of the user. Alternatively, in some embodiments, the temperature sensor 112 is woven into the rear portion 104, gusset 106, or waistband 108 of the wearable article 101.

The microcontroller 116 is communicatively coupled to the temperature sensor 112 via the first connector 120 and the second connector 122. The microcontroller 116 is configured to apply an input signal to the temperature sensor 112 via the first connector 120 and receive a feedback signal via the second connector 122. As will be described, the feedback signal is used to determine the temperature at the temperature sensor 112.

The first connector 120 and the second connector 122 are referred to collectively as connectors 120, 122. In some embodiments, the connectors 120, 122 are wire connectors. In some embodiments, the connectors 120, 122 are disposed on the surface of the textile. In some embodiments, the connectors 120, 122 are disposed between two layers of textile. In some examples, the connectors 120, 122 comprise conductive yarns which are woven or sewn into the textile.

In some embodiments, the connectors 120, 122 are wireless connectors. The microcontroller 116 includes a wireless transceiver for communication wirelessly with the temperature sensor 112. Examples of a wireless communication transceivers include a Wi-Fi module, a Bluetooth™ module, a radiofrequency identification (RFID) tag, near field communication (NFC) technology, and the like.

In some embodiments, the microcontroller 116 includes a Microcontroller Unit (MCU) such as the Arduino™ UNO (Arduino: New York, United States) or the Arduino™ Nano 33 BLE (Arduino: New York, United States). However, the microcontroller 116 is not particularly limited to these specific controllers.

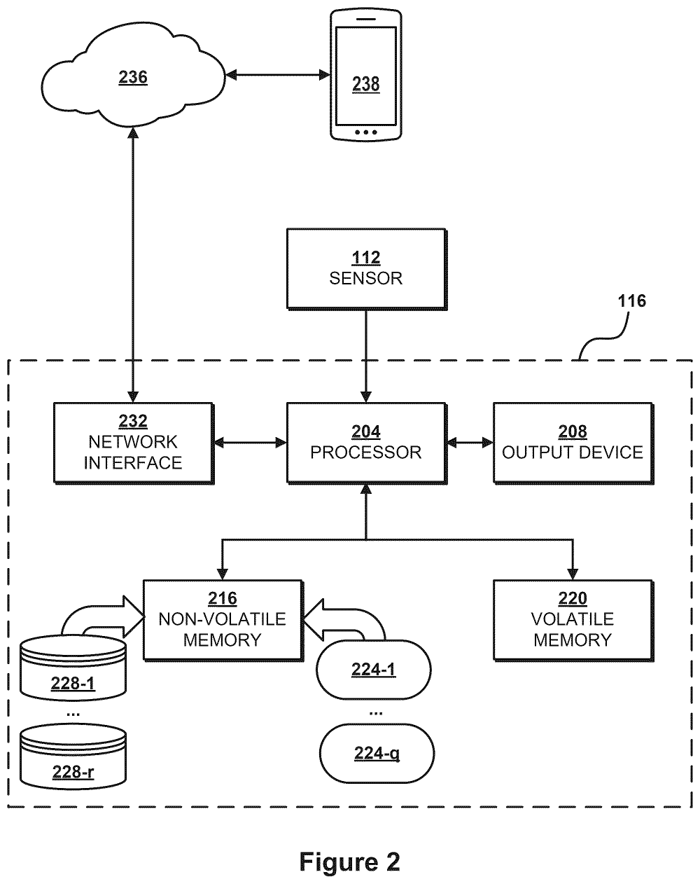

Referring to FIG. 2 a block diagram of the microcontroller 116 is illustrated. The microcontroller 116 includes a processor 204, one or more output device 208, non-volatile memory 216, volatile memory 220, and network interface 232.

The processor 204 is configured to receive a feedback signal from temperature sensor 112 and process the feedback signal to generate an output. In some embodiments, the processor 204 is implemented as a plurality of processors. In some embodiments, the processor 204 is implemented as one or more multi-core processors. In some embodiments, the processor 204 is configured to execute different programing instructions responsive to the feedback received from the temperature sensor 112 and to control the one or more output device 208 to generate output thereon.

To fulfill its programming functions, the processor 204 is configured to communicate with one or more memory units, including the non-volatile memory 216 and the volatile memory 220. The non-volatile memory 216 is based on any persistent memory technology, such as an Erasable Electronic Programmable Read Only Memory (“EEPROM”), flash memory, solid-state hard disk (SSD), other type of hard-disk, or combinations of them. The non-volatile memory 216 may also be described as a non-transitory computer readable media. Also, more than one type of non-volatile memory 216 may be provided.

The volatile memory 220 is based on any random-access memory (RAM) technology. For example, volatile memory 220 can be based on a Double Data Rate (DDR) Synchronous Dynamic Random-Access Memory (SDRAM). Other types of volatile memory 220 are contemplated.

In some embodiments, the processor 204 is communicatively coupled to a network 236 via the network interface 232. Suitable examples of network interfaces may include a Wi-Fi module, a Bluetooth™ module, a radio frequency identification (RFID) tag, the like, or a combination thereof.

The network interface 232 can be used to communicatively couple the microcontroller 116 with a computing device 238. The computing device 238 can be any type of human-machine interface for interacting with the wearable device 100. For example, the computing device 238 can be a smartphone, personal computer, tablet computer, smartwatch, smart home systems, and any other device that can be used to receive and send content. In some embodiments, the computing device 238 is operated by a user associated with a respective identifier object that uniquely identifies the user accessing the computing device 238. The computing device 238 may comprise a processor for executing programming instructions in the form of applications. The computing device 238 may further include non-volatile memory. The computing device 238 may further include volatile memory. The computing device 238 may further include an output device. Any description of the processor 204 may apply to the processor of the computing device 238 and vice versa. Likewise, any description of the non-volatile memory 216 and the volatile memory 220 may apply to the non-volatile and volatile memory of the computing device 238 and vice versa. Similarly, any description of the output device 208 may apply to the output of the computing device 238 and vice versa.

Programming instructions in the form of applications 224 are typically maintained, persistently, in the non-volatile memory 216 and used by the processor 204 which reads from and writes to the volatile memory 220 during the execution of the applications 224. Various methods discussed herein can be coded as one or more applications 224. (Generically referred to herein as “application 224” or collectively as “applications 224”. This nomenclature is used elsewhere herein.)

One or more tables or databases 228 are maintained in non-volatile memory 516 for use by applications 224.

In some embodiments, the microcontroller 116 includes an ohmmeter (not shown) for measuring the resistance in the temperature sensor 112.

The microcontroller 116 further comprises a power source (not shown) for applying the input signal to the temperature sensor 112 and powering the microcontroller 116. The power source may include a battery, a power port, a self-charging power pack, a power source that converts body energy into electricity, or a combination thereof. The battery may be rechargeable or non-rechargeable battery. The battery may be removable or permanent. In some embodiments, the power port may be configured to receive power from an external source to charge the battery.

In some embodiments, the power source comprises one or more lithium-ion batteries to power the sensor and microcontroller 116. The microcontroller 116 may be powered via a universal serial bus (USB) port which is coupled to the power source. The accompanying batteries might be stored in a 3D-printed box and located on the wrist of the user ensuring comfort and safety while using the wearable device.

In further examples, the power source includes the series DMW-BLF19 (Panasonic™). The 7.2V, 1860 mAh battery potentially works for up to 24 hours if the operating voltage of the microcontroller 116 is between 7 to 14 V. Other power sources such as fully self-charging power packs (FSPP) or power sources that work use body heat to store energy and use that can be other power sources used in this system.

Another suitable option is the Molex™ electronic battery (Mouser Electronics: Kitchener, Canada) which is a very light and thin battery. This thin-film battery may be used to power the microcontroller 116 and the temperature sensor 112. The Molex™ electronic battery has a shelf life of about two years and can operate in a humidity of about 20% to about 90% and in a temperature range of about −35° C. to about 50° C. It is a 3V battery with an initial internal resistance of about 90 ohms and a peak current (maximum) of about 8 to about 10 mA. It is bendable and small. It has a minimum bending radius of about 35.00 mm, a thickness of about 0.70 mm, and a width of about 36.00 mm.

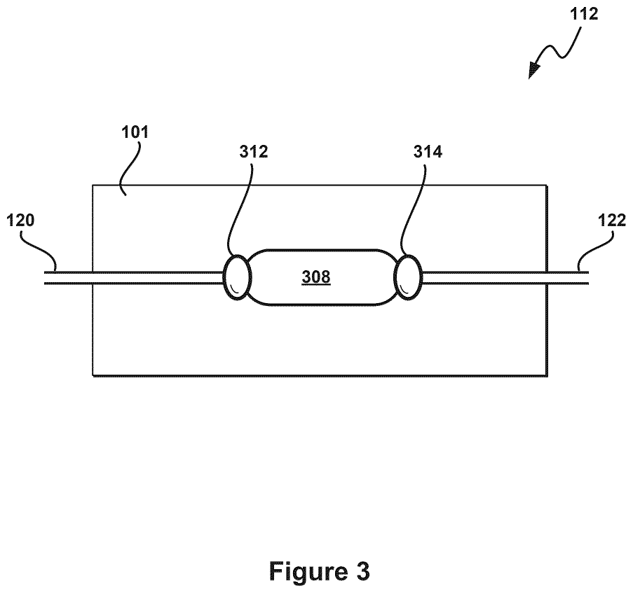

Referring to FIG. 3, a top elevation view of the temperature sensor 112 is illustrated. The temperature sensor 112 is disposed on a textile 304. That is, the textile may provide a substrate on which the temperature sensor 112 is formed. In some embodiments, the textile 304 is the wearable article 101. In some embodiments, the textile 304 attachable to the wearable article 101.

The temperature sensor 112 includes a sensing layer 308. The sensing layer 308 is coupled to the microcontroller 116 via the first connector 120 and the second connector 122. The temperature sensor 112 further includes a first electrode 312 and a second electrode 314.

The sensing layer 308 comprises a temperature-sensitive compound. The temperature sensitive compound includes Poly(3,4-ethylenedioxythiophene):poly(styrenesulfonate) (PEDOT:PSS). PEDOT:PSS is an organic semiconductor known for its temperature sensitivity. The temperature-sensitive compound further comprises reduced graphene oxide (rGO). The rGO is dispersed within the temperature-sensitive compound. The dispersion of the rGO within the temperature-sensitive compound enhances temperature sensitivity, conductivity, and environmental stability of the PEDOT:PSS. The relative amounts of PEDOT:PSS and rGO may vary. In some embodiments, the ratio of PEDOT:PSS/rGO is about 4:1 wt. %.

In some embodiments, the temperature-sensitive compound further includes ethylene glycol. In some embodiments, the temperature-sensitive compound further includes 4-dodecylbenzenesulfonic acid (DBSA). In some embodiments, the temperature-sensitive compound further includes (3-glycidyloxypropyl) trimethoxysilane (GOPS). In some embodiments, the temperature-sensitive compound further includes Dimethyl sulfoxide (DMSO). GOPS and DMSO may decrease environmental effects, such as humidity, on temperature sensing.

In some embodiments, the sensing layer 308 is manufactured by inkjet-printing a thin layer of the temperature-sensitive compound onto the surface of the textile 304. Any suitable inkjet printer may be used to apply the temperature-sensitive compound to the textile. In a specific-non-limiting example, the inkjet printer includes a piezoelectric inkjet nozzle with a diameter of about 30 μm (MJ-ATP-01-60-8MX, Microfab Technologies, Inc. Plano, TX). To stabilize jetting, a trapezoidal bipolar waveform of 60V peak-to-peak may be applied to the nozzle to jet the temperature-sensitive compound.

To facilitate inkjet printing, the temperature-sensitive compound includes about: 80-90 wt % of an aqueous dispersion of PEDOTPSS, wherein the PEDOT:PSS solid content is approximately 1.3 wt % (e.g., Clevios PH1000); 0.5-2 wt % rGO, provided as a dispersion of 1 wt % rGO in water or dimethyl sulfoxide (DMSO); 1-3 wt % 4-dodecylbenzenesulfonic acid (DBSA), relative to the solid content of PEDOT:PSS; 0.1-0.5 wt % (3-glycidyloxypropyl)trimethoxysilane (GOPS); 5-10 wt % ethylene glycol; 3-7 wt % dimethyl sulfoxide (DMSO); and deionized water comprising the balance to 100 wt %. The ethylene glycol acts as a co-solvent to adjust viscosity and evaporation rate The GOPS acts as a crosslinking agent. The DMSO enhances conductivity and ink stability.

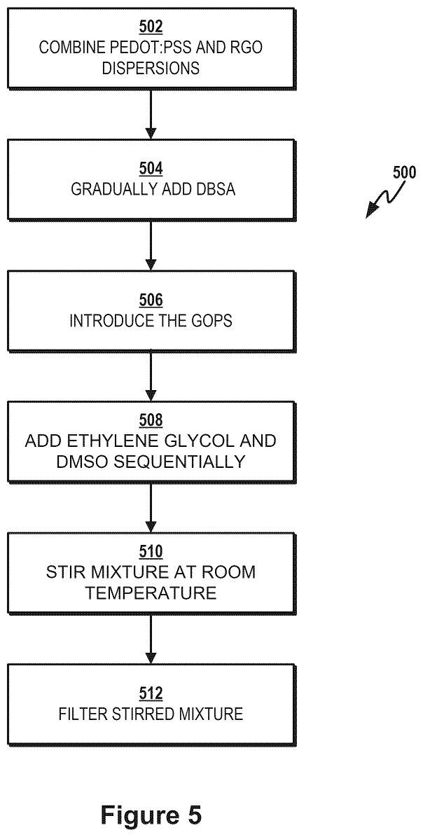

Referring to FIG. 5, a flow chart of a method for preparing the temperature-sensitive compound is illustrated generally by numeral 500. At block 502, the PEDOT:PSS aqueous dispersion is combined with the rGO dispersion under continuous stirring. Next, at block 504 the DBSA is added gradually to ensure uniform doping of the PEDOT:PSS. At block 506, the GOPS is introduced to crosslink the polymer matrix, improving environmental resistance. At block 508, the ethylene glycol and DMSO are added sequentially to adjust the rheological properties. At block 510, the resulting mixture is stirred for 2-4 hours at room temperature. At block 512, the stirred mixture is filtered through a 0.45 μm filter.

The Ohnesorge number (Oh) is a dimensionless quantity that governs the jetting behavior of inks in inkjet printing and is calculated as follows:

$$Oh = \frac{μ}{\sqrt{ρ \cdot σ \cdot D}} \qquad Equation 1$$

In equation 1:
μ=viscosity of the ink (Pa·s),
ρ=density of the ink (kg/m³),
σ=surface tension of the ink (N/m),
D=nozzle diameter (m).

For stable inkjet printing, the inverse Ohnesorge number (Z) should fall within the range:

$$1 < Z < 10 , Z = \frac{1}{Oh}$$

For the present ink composition:
μ=12 mPa\cdotps
ρ=1000 kg/m3 (approximated for water-based inks),
σ=35 mN/m
D=30 μm=3×10−5 m

$$Oh = \frac{0.012}{\sqrt{1000 \times 0.035 \times 3 \times 1 {0}^{- 5}}} = 0 \text{.37}$$

$$Z \approx 2. 7$$

The calculated Z≈2.7 confirms that the ink composition described above falls within the stable jetting window (1<Z<10), allowing consistent droplet formation in inkjet printing applications.

The first connector 120 and the second connector 122 are coupled to the temperature sensor 112 via the first electrode 312 and the second electrode 314, respectively. In some embodiments, the first electrode 312 is spaced apart from the second electrode 314. In some embodiments, the first electrode 312 and the second electrode 314 are coupled to the sensing layer 308 at opposite sides thereof, as shown in FIG. 3.

The first electrode 312 and the second electrode 314 comprise a silver conductive paste. Some examples include PELCO® High Performance Silver Paste or Sigma-Aldrich® Silver Conductive Paste (CAS Number: 7440-22-4). The silver conductive paste may be extrusion-printed or drop-cast onto the textile 304. In some embodiments, where the silver conductive paste is extrusion-printed, the conductive paste may be extrusion printed using a Voltera V-One™ PCB Printer.

The microcontroller 116 transmits the input signal on the first electrode 312 and measures a feedback signal, responsive to the input signal, on the second electrode 314. Based on the input signal and the feedback signal, the microcontroller 116 is configured to measure the resistance of the sensing layer 308. The microcontroller 116 is further configured to determine the temperature of the temperature-sensitive compound based on the resistance. When the wearable device 100 is worn such that the sensing layer 308 is positioned against, or proximal to, the user's skin, the temperature determined by the microcontroller 116 is approximately the same as the skin temperature of the user.

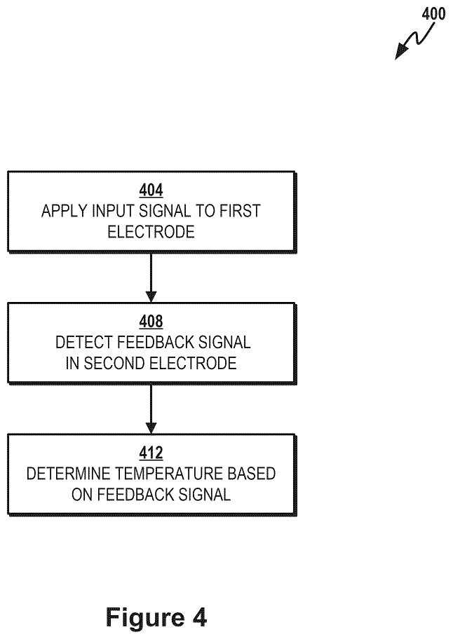

Referring to FIG. 4, a flow chart of a method for measuring body temperature using the temperature sensor of FIG. 3 is illustrated generally by numeral 400.

At block 404, the input signal is applied to the first electrode 312. In the wearable device 100, block 404 is performed by the microcontroller 116 which applies the input signal to the first electrode 312.

In some embodiments, the input signal in an analog signal having a current between about 0.01 mA and about 0.1 mA, although the input signal is not particularly limited.

In some embodiments, the input signal is applied continuously. In some embodiments the input signal is applied periodically. In some embodiments, the duration between each application of the input signal can range from about 1 second to about 30 minutes. In some examples, the input signal is applied every 10 seconds. In some examples, the input signal is applied every 30 seconds. In some examples, the input signal is applied every 60 seconds. In some examples, the input signal is applied every 2 minutes. In some examples, the input signal is applied every 10 minutes.

At block 408 it is determined whether the feedback signal is detected in the second electrode 314. In the wearable device 100, block 408 is performed by the microcontroller 116 which detects a feedback signal in the second electrode 314. The feedback signal is responsive to the input signal.

At block 412 the temperature at the sensing layer 308 is computed based on the feedback signal. In the wearable device 100, block 412 is performed by the processor 204 which determines the temperature based on the input signal applied at block 404 and the feedback signal received at block 408.

In some embodiments, the processor 204 determines the resistance of the sensing layer 308 based on the input signal and the feedback signal and computes the temperature based on the resistance. The higher the conductivity, the higher the temperature and vice versa. In some embodiments, the processor 204 computes a specific temperature value based on the determined resistance.

The temperature value may be expressed as a numerical value expressed in degrees Celsius, degrees Fahrenheit, Kelvin, or any suitable unit.

After computing the temperature, the microcontroller 116 transmits the temperature to the computing device 238. In some embodiments, the microcontroller 116 controls the computing device 238 to display the temperature value.

In view of the specification, it will be apparent to a person of skill in the art temperature sensor affords certain advantages over the prior art. For example, the dispersion of the rGO with the PEDOT:PSS in the temperature sensitive compound serves a dual purpose. That is, the dispersion of the rGO improves the overall conductivity of the sensor material, making it more responsive to temperature changes. Additionally, dispersion of the rGO enhances the stability of PEDOT:PSS, ensuring reliable and consistent performance.

Further, applying the temperature-sensitive compound directly onto a textile makes the sensor suitable for wearable technology or smart textiles. The fabric provides flexibility and comfort, making it practical for applications where traditional rigid sensors might be less suitable.

The many features and advantages of the invention are apparent from the detailed specification and, thus, it is intended by the appended claims to cover all such features and advantages of the invention that fall within the true spirit and scope of the invention. Further, since numerous modifications and changes will readily occur to those skilled in the art, it is not desired to limit the invention to the exact construction and operation illustrated and described, and accordingly all suitable modifications and equivalents may be resorted to, falling within the scope of the invention.

What is claimed is:

1. A temperature sensor comprising:
a sensing layer comprising:
a textile;
a temperature-sensitive compound, applied to a surface of the textile, including poly(3,4-ethylenedioxythiophene):poly(styrenesulfonate) (PEDOT:PSS) and reduced graphene oxide (rGO) dispersed within the temperature-sensitive compound;
two spaced-apart silver electrodes, electrically coupled to the sensing layer, including a first electrode and a second electrode; and
a microcontroller configured to:
apply an input signal to the sensing layer via the first electrode;
receive a feedback signal via the second electrode; and
compute a temperature based on the feedback signal.

2. The temperature sensor of claim 1, wherein the textile is part of a wearable article.

3. The temperature sensor of claim 2, wherein the temperature sensor is positioned on the wearable article to contact the skin of a user when the wearable article is worn.

4. The temperature sensor of claim 1, wherein the sensing layer is applied directly to the textile via inkjet-printing.

5. The temperature sensor of claim 1, wherein the electrodes comprise a silver conductive paste applied to the textile via drop-casting or extrusion-printing.

6. The temperature sensor of claim 1, wherein the microcontroller comprises a wireless transceiver configured to transmit the computed temperature to an external computing device.

7. The temperature sensor of claim 1, wherein the temperature-sensitive compound comprises about: 80-90 wt % of an aqueous dispersion of PEDOT:PSS, wherein the PEDOT:PSS solid content is approximately 1.3 wt %; 0.5-2 wt % rGO, provided as a dispersion of 1 wt % rGO in water or dimethyl sulfoxide (DMSO); 1-3 wt % 4-dodecylbenzenesulfonic acid (DBSA), relative to the solid content of PEDOT:PSS; 0.1-0.5 wt % (3-glycidyloxypropyl)trimethoxysilane (GOPS); 5-10 wt % ethylene glycol; 3-7 wt % dimethyl sulfoxide (DMSO); and deionized water comprising the balance to 100 wt %.

8. A method of manufacturing a temperature sensor comprising:
inkjet-printing a sensing layer onto a textile, the sensing layer comprising a temperature-sensitive compound including a mixture of poly(3,4-ethylenedioxythiophene):poly(styrenesulfonate) and reduced graphene oxide dispersed within the temperature-sensitive compound; and
applying two spaced-apart silver electrodes to the textile, such that the two electrodes are electrically coupled to the sensing layer.

9. The method of claim 8, wherein the textile is part of a wearable article.

10. The method of claim 9, wherein the temperature sensor is inkjet-printed on the wearable article at a position to contact the skin of a user when the wearable article is worn.

11. The method of claim 8, wherein applying the two spaced-apart silver electrodes comprises drop-casting a silver conductive paste onto the textile.

12. The method of claim 8, wherein applying the two spaced-apart silver electrodes comprises extrusion-printing a silver conductive paste onto the textile.

13. The method of claim 8, wherein the temperature-sensitive compound comprises about: 80-90 wt % of an aqueous dispersion of PEDOT:PSS, wherein the PEDOT:PSS solid content is approximately 1.3 wt %; 0.5-2 wt % rGO, provided as a dispersion of 1 wt % rGO in water or dimethyl sulfoxide (DMSO); 1-3 wt % 4-dodecylbenzenesulfonic acid (DBSA), relative to the solid content of PEDOTPSS; 0.1-0.5 wt % (3-glycidyloxypropyl)trimethoxysilane (GOPS); 5-10 wt % ethylene glycol; 3-7 wt % dimethyl sulfoxide (DMSO); and deionized water comprising the balance to 100 wt %.

14. The method of claim 13, wherein preparing the temperature-sensitive compound comprises:
combining the PEDOT:PSS aqueous dispersion with the rGO dispersion under continuous stirring;
adding the DBSA gradually to ensure uniform doping of the PEDOT:PSS;
introducing the GOPS;
adding the ethylene glycol and DMSO sequentially;
stirring the mixture at room temperature; and
filtering the stirred mixture through a filter.
